(19) United States
(12) Patent Application Publication
(10) Pub. No.: US 2013/0276869 A1
(43) Pub. Date: Oct. 24, 2013

(54) Flag-Type Hybrid Solar Cell in Which a Solar Cell Using a Nanowire and a Nanogenerator Using the Piezoelectric Effect are Coupled Together, and Method for Manufacturing Same

(71) Applicants: Im-Jun No, Incheon (KR); Paik Kyun Shin, Incheon (KR)

(72) Inventors: Im-Jun No, Incheon (KR); Paik Kyun Shin, Incheon (KR)

(73) Assignee: INHA-INDUSTRY PARTNERSHIP INSTITUTE, Incheon (KR)

(21) Appl. No.: 13/977,367

(22) PCT Filed: Dec. 27, 2011
(86) PCT No.: PCT/KR2011/010149

§ 371 Date: Jul. 9, 2013

(30) Foreign Application Priority Data
Dec. 31, 2010 (KR) 10-2010-0140474

(51) Int. Cl. H01L 31/058; H01L 31/18

(52) U.S. Cl. CPC H01L 31/0583; H01L 31/1884
USPC 136/251; 438/66

(57) ABSTRACT

A flag type hybrid solar cell is provided, which combines nano-wire solar cells using nano-wires and nano-generators using piezoelectric effect, and which is usable anywhere as long as there are sun and the winds, since the nano-wire solar cells absorb solar beam and generate electromotive force during the days, while the nano-generators using piezoelectric effect generate electromotive force with micro vibration of the nano-wires in response to winds, and thus is capable of providing more power generation during the days, by providing the power generation by the nano-wire solar cells added with power generation by the nano-generators using piezoelectric effect.

### BACKGROUND

1. Field of the Invention

The present invention relates to a solar cell using nano-wire, and a manufacturing method thereof, and more particularly, to a flag type hybrid solar cell capable of generating power at all times and irrespective of presence or absence of solar energy or location thereof, by simultaneously utilizing solar beam and wind power with a combination of a solar cell using nano-wire and nano-generator using piezoelectric effect, and a manufacturing method thereof.

Further, the present invention refers to Korean Patent Application Nos. 10-2010-0140474, 10-2011-0082817, and 10-2011-0118195, filed respectively on Dec. 31, 2010, Aug. 19, 2011, and Nov. 14, 2011, by the same inventors, in the Korean Intellectual Property Office, the disclosure of which is incorporated herein by reference in its entirety.

2. Description of the Related Art

Generally, a solar cell converts energy from solar beam into electric energy by utilizing nature of semiconductor, and is divided into various categories depending on materials used for light absorbing layer.

First, a solar cell using silicon as a light absorbing layer is generally divided into a single crystalline silicon solar cell, a polycrystalline silicon solar cell, and amorphous silicon solar cell, depending on phases of the silicon.

Additionally, the conventional solar cell is divided into CdTe, or CIS (CuInSe2) compound thin layer solar cell, dye-sensitized solar cell or organic solar cell.

Further, a general conventional solar cell uses zinc oxide (ZnO) as a transparent electrode, and such ZnO membrane may be deposited on the substrate using method such as sputtering, atmosphere pressure chemical vapor deposition (APCVD), low pressure chemical vapor deposition (LPCVD), or metal organic chemical vapor deposition (MOCVD).

The process is generally performed at high temperature for the purpose of improving texturing and electric conductivity, and accordingly, disadvantages such as larger-sized substrate and subsequent bending problem can occur. Furthermore, since polycrystalline zinc oxide is deposited onto the substrate, there is difficulty of Ohmic contact in the process of contacting with thin layer silicon.

For the reasons including those explained above, the overall efficiency of solar cell deteriorates.

Further, a conventional solar cell generally has shortcoming of being overly sensitive to the angle of the sun, which means that the conventional solar cell is practically not able to generate power at dawn, after sunset, at cloudy or rainy days, while this can generate the largest energy when the sun is at high noon. Therefore, the conventional solar cell has drawback of fluctuating energy generation depending on amount of sunshine.

Accordingly, to overcome the disadvantages, drawbacks and problems of the conventional solar cell, it would be desirable if a new solar cell is provided, which is capable of power generation irrespective of the amount of sunshine, but currently, no such apparatus or method that can suffice the demands is available.

### SUMMARY

Exemplary embodiments of the present inventive concept overcome the above disadvantages and other disadvantages not described above. Also, the present inventive concept is not required to overcome the disadvantages described above, and an exemplary embodiment of the present inventive concept may not overcome any of the problems described above.

A technical object is to provide a flat type hybrid solar cell combining a solar cell using nano-wire and a nano-generator using piezoelectric effect, which are capable of generating a constant electromotive force irrespective of the amount of sunshine and even at night, by generating energy with vibration of the nano-wire generated due to wind, and a manufacturing method thereof.

Further, it is another object of the present invention to provide a flag type hybrid solar cell combining a solar cell using nano-wire and a nano-generator using piezoelectric effect, which is capable of maximizing efficiency of the solar cell compared to conventional solar cell using nanorwire, and a manufacturing method thereof.

According to one embodiment, a flag type hybrid solar cell capable of generating electricity irrespective of location of sun or presence or absence of sun beams, is provided, which may include a plurality of solar cells formed from a flexible substrate which is deformable by winds, and a frame which fixes the solar cells, in which the solar cells may include a plurality of nano-wire solar cells which generate electricity from solar beam using nano-wires, and a plurality of nano-generators which generate electricity using piezoelectric effect, in which the nano-wire solar cells and the nano-generators using piezoelectric effect may be connected to each other in a perpendicularly symmetrical relation to each other.

The nano-wire solar cells may include substrates, transparent electrodes formed on the substrates, seed layers formed no the transparent electrodes, a plurality of nano-wires grown on the seed layers and formed into conical shape, electron transfer layers which facilitate transfer of electrons collected at the nano-wires, metal thin layers formed on the electron transfer layers, a plurality of carbon nano-tubes which are syntheied with metal particles contained in the metal thin layers, active layers formed as a result of the synthesis of the carbon nano-tubes and coating of blended polymer, hole transfer layers formed on the active layers to facilitate the transfer of the holes, and metal electrodes formed on the hole transfer layers. The transparent electrodes may be formed from ITO.

The nano-wires may be formed into the conical shape by dry or wet etching.

The electron transfer layers may be formed by coating thin lithium fluoride (Lif).

The metal thin layers may be formed by coating gold (Au) or nickel (Ni) as a catalyst for the synthesis of the carbon nano-tubes.

The active layers may be formed as a result of synthesizing the carbon nano-tubes, doped in n-type, to the metal particles contained in the metal thin layers, and coating blended polymer solution.

The polymer solution may be coated using spin coating or air spraying.

The electron transfer layers may be formed by depositing poly(3,4-ethylenedioxythiophene) poly(styrenesulfonate) (PDOT:PSS).

The metal electrodes may be formed by using gold (Au) or a material having 5.2 eV of work function.

The nano-generators using piezoelectric effect may include upper and lower substrates arranged on upper and lower surfaces, respectively, seed layers arranged on the lower substrates, a plurality of nano-wires grown on the seed layers in perpendicular direction, respectively, lower electrodes arranged between the lower substrates and the seed layers to transmit electricity generated at the nano-wires to outside, and formed from conductive material, and upper electrodes in serrated form formed on the upper substrates, energy accumulating means for accumulating the electricity transmitted from the respective electrodes, supports arranged on both left and right ends of the lower substrates to prevent contact between the upper substrates with the lower substrates and to maintain a predetermined interval therebetween, and coating layers coated all around the nano-wires, respectively

The nano-wires may be formed into conical shape.

The coating layers may be formed from polymer material comprising polyvinylidene fluoride.

In one embodiment, a method for manufacturing a flag type hybrid solar cell capable of generating electricity irrespective of location of sun or presence or absence of sun beams, is provided, which may include fabricating a plurality of solar cells deformable by winds, using a flexible substrate, and fabricating a frame to fix the solar cells, in which the fabricating the plurality of solar cells may include fabricating a plurality of nano-wire solar cells which generate electricity from solar beam using nano-wires, fabricating a plurality of nano-generators which generate electricity using piezoelectric effect, and connecting the nano-wire solar cells and the nano-generators using piezoelectric effect to each other in a perpendicularly symmetrical relation to each other.

The fabricating the nano-wire solar cells may include forming transparent electrodes on substrates, forming seed layers to grow nano-wires on the transparent electrodes, growing a plurality of nano-wires on the seed layers, shaping the grown nano-wires into conical configuration, forming electron transfer layers on the respectively-shaped nano-wires, forming metal thin layers on the electronic transfer layers for synthesis of the nano-wires with carbon nano-tubes, synthesizing metal particles contained in the metal thin layers with the carbon nano-tubes by coating the carbon nano-tubes on the metal thin layers, forming active layers on the synthesized carbon nano-tubes, forming hole transfer layers on the active layers, and forming metal electrodes on the hole transfer layers.

The forming the transparent electrodes may use ITO. The shaping may include shaping the nano-wires into the conical configuration by dry or wet etching.

The forming the electron transfer layers may include coating Lif.

The forming the metal thin layers may include coating gold (Au) or nickel (Ni).

The forming the active layers may include synthesizing the metal particles contained in the metal thin layers with the carbon nano-tubes which are n-type doped, and coating blended polymer solution.

The forming the active layers may include coating the polymer solution using spin coating or air spraying.

The forming the hole transfer layers may include depositing PDOT:PSS.

The forming the metal electrodes may include using gold (Au) or a material corresponding to 5.2 eV of work function.

The fabricating the nano-generators using piezoelectric effect may include forming upper and lower substrates arranged on upper and lower surfaces, respectively, forming lower electrodes formed from conductive material on the lower substrates, forming seed layers on the lower substrates to grow nano-wires, forming serrated upper electrodes on the upper substrates, installing energy accumulating means to accumulate electricity transmitted from the respective electrodes, installing supports on both left and right ends of the lower substrate to prevent contact between the upper substrates and the lower substrates and to maintain a predetermined interval therebetween, growing a plurality of nano-wires on the seed layers to a perpendicular direction, and coating layers all around the respective nano-wires.

The growing the nano-wires may include forming ends of the nano-wires to a conical shape.

The coating may include coating a polymer material comprising polyvinylidene fluoride (PVDF) all around the nano-wires.

According to various embodiments, a flag type hybrid solar cell is provided, which combines nano-wire solar cells and nano-generators using piezoelectric effect, which is easy to fabricate, usable anywhere as long as there are sun and the winds, and easy to install as it requires simple planting, and thus provides environmentally-friendly green energy.

According to various embodiments, compared to a conventional example where the solar cells are considerably influenced depending on the angle of the sun or magnitude of the solar beam, a flag type hybrid solar cell and a manufacturing method thereof provide solution, since a combination of nano-wire solar cells and nano-generators using piezoelectric effect can generate electricity at all times without being influenced by the location of the sun, angle of the sun beam or presence or absence of the sun beam.

Further, according to various embodiments, due to use of flexible substrates, which are transparent both on upper and lower substrates, more lights are received to generate more electron-hole pairs compared to the conventional nano-wire solar cells, so that area to generate electron-hole pairs increases, and interface to isolate electron-hole is maximized. As a result, a flag type hybrid solar cell having a combination of nano-wire solar cells and nano-generators using piezoelectric effect and manufacturing method thereof can provide more electromotive force compared to the conventional examples.

### BRIEF DESCRIPTION OF THE DRAWINGS

The above and/or other aspects of the present inventive concept will be more apparent by describing certain exemplary embodiments of the present inventive concept with reference to the accompanying drawings, in which:

FIG. 1 illustrates the overall constitution of a flag type hybrid solar cell having a combination of nano-wire solar cells using nano-wires and nano-generators using piezoelectric effect, according to an embodiment of the present invention;

FIG. 2 schematically illustrates the detailed constitution of solar cells of the flag type hybrid solar cell of FIG. 1 having a combination of nano-wire solar cells using nano-wires and nano-generators using piezoelectric effect, according to an embodiment of the present invention;

FIG. 3 illustrates a constitution of nano-wire solar cells using nano-wires in the flag type hybrid solar cell of FIG. 1 having a combination of nano-wire solar cells using nano-wires and nano-generators using piezoelectric effect and a manufacturing method thereof, according to an embodiment of the present invention;

FIG. 4 illustrates a constitution of nano-generators using piezoelectric effect in the flag type hybrid solar cell of FIG. 1 having a combination of nano-wire solar cells using nano-wires and nano-generators using piezoelectric effect and a manufacturing method thereof, according to an embodiment of the present invention; and

FIG. 5 schematically illustrates the detailed constitution of the nano-wires of the nano-generators using piezoelectric effect of FIG. 4.

### BEST MODE

Certain exemplary embodiments of the present inventive concept will now be described regarding a flag type hybrid solar cell combining a solar cell using nano-wire and a nano-generator using piezoelectric effect and a manufacturing method thereof in greater detail with reference to the accompanying drawings.

It is to be understood that the disclosure provided herein relates only to certain embodiments of the invention, and these should not be construed as limiting.

The present invention thus relates to a flag type hybrid solar cell combining a solar cell using nano-wire and a nano-generator using piezoelectric effect, which is formed into a flag configuration to multiply the vibration of the nano-generator with piezoelectric property, is usable almost anywhere as long as there are sun and wind, requires simple fabrication and installation, and thus is capable of constantly generating electricity without being affected by the location of the sun, angle of sunbeam or presence or absence of the sunbeam, thereby resolving shortcomings of the conventional solar cell associated with sensitivity to angle of sun or magnitude of solar beam, and a manufacturing method thereof.

Further, the present invention relates to a flag type hybrid solar cell combining a solar cell using nano-wire and a nano-generator using piezoelectric effect, which is capable of increasing an area to generate electron-hole pairs compared to a conventional solar cell using nano-wire, and at the same time, maximizing interface to separate electron-hole pairs, thereby generating more automotive force than the conventional solar cell using nano-wire, and a manufacturing method thereof.

Certain exemplary embodiments of the present inventive concept will now be described regarding a flag type hybrid solar cell combining a solar cell using nano-wire and a nano-generator using piezoelectric effect and a manufacturing method thereof in greater detail with reference to the accompanying drawings.

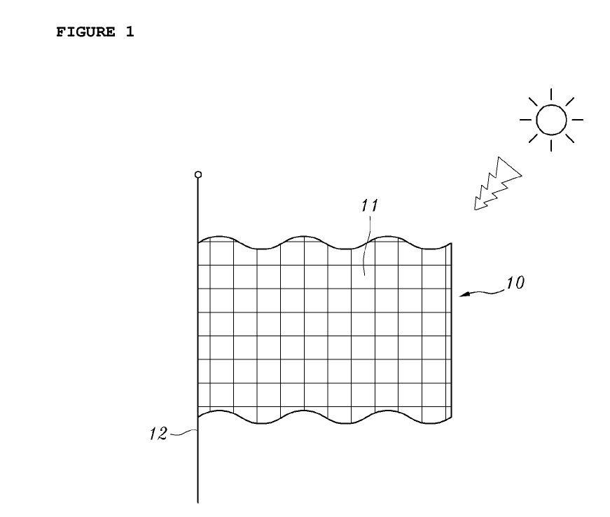

FIG. 1 is a schematic view illustrating an overall constitution of a flag type hybrid solar cell combining a solar cell using nano-wire and a nano-generator using piezoelectric effect, according to an embodiment of the present invention.

Referring to FIG. 1, a flag type hybrid solar cell combining a solar cell using nano-wire and a nano-generator using piezoelectric effect, according to an embodiment of the present invention, includes a plurality of solar cells 11 formed from flexible substrates and thus are deformable by the winds, and a frame 12 to fix the solar cells 11, and thus forms a flag-like configuration.

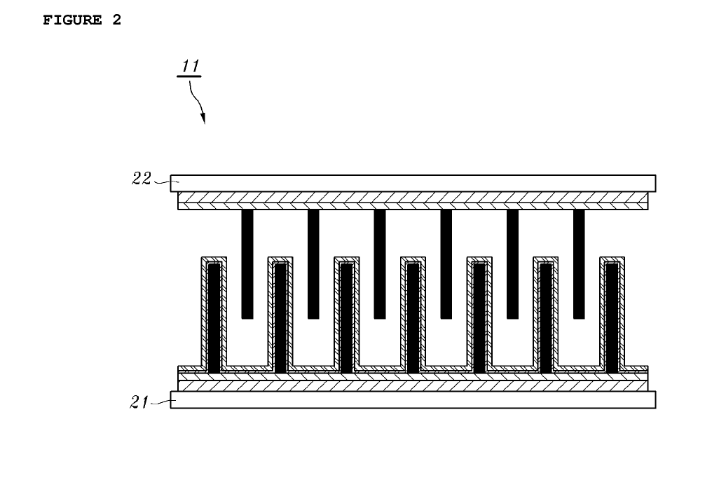

Referring to FIG. 2, the solar cells 11 include a plurality of nano-wire solar cells 21 which generate electricity from sunbeam using nano-wire, and a plurality of nano-generators which are bonded vertically and symmetrically to the nano-wire solar cells 21 to generate electricity based on piezoelectric effect.

Accordingly, the flag type hybrid solar cell 10 configured as explained above is capable of generating electricity at the nano-wire solar cells 21 from the sunbeam, while, at the same time, the flexible substrates allow dynamic movement in a flag-like pattern when planted at a windy place and thus generates energy via the nano-generators 22 based on piezoelectric effect.

Further, the solar cell 11 is capable of generating electron-hole pairs by being exposed to more light and without being influenced by the angle of the sun, because all the upper and lower substrates are made from transparent, flexible substrates.

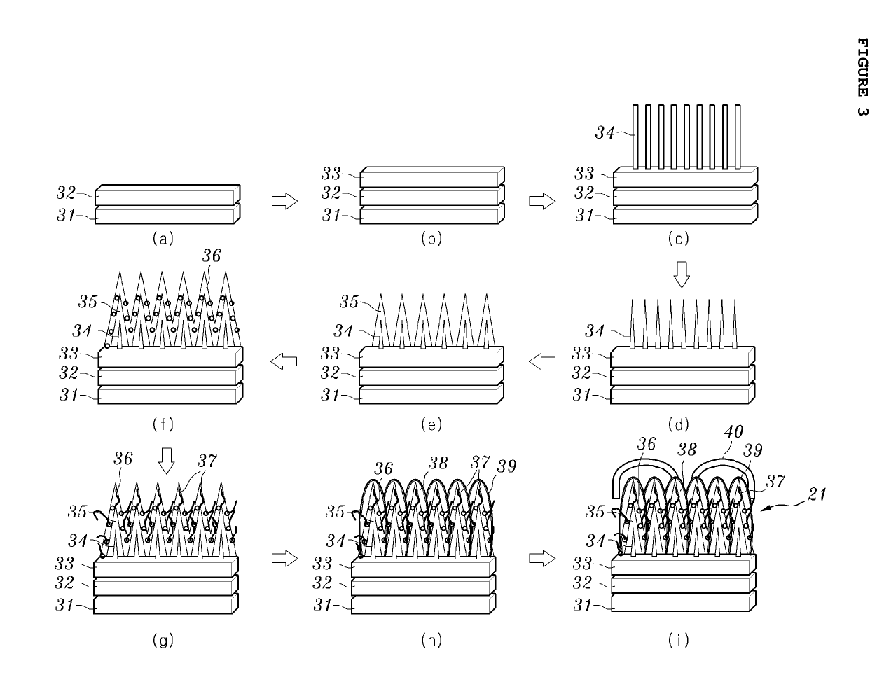

Referring continuously to FIGS. 3 to 5, the constitution of the nano-wire solar cells 21 and the nano-generators 22 using piezoelectric effect will be explained in greater detail below.

First, FIG. 3 is a schematic view illustrating a constitution of nano-wire solar cells 21 of the flag-type hybrid solar cell 10 of FIG. 1, and a manufacturing method thereof, according to an embodiment of the present invention.

Referring to FIG. 3, the nano-wire solar cells 21 according to an embodiment of the present invention include substrates 31, transparent electrodes 32 formed on the substrates 31, seed layers 33 formed on the transparent electrodes 32 and a plurality of nano-wires 34 grown on the seed layers 33, electron transfer layers 35 to enable transfer of the electrons when these are collected via the nano-wires 34, metal thin layers 36 formed on the electron transfer layers 35, a plurality of carbon nanotubes 37 synthesized with the metal particles contained in the metal thin layers 36, active layers 38 formed by coating blended polymer after the formation of the carbon nano-tubes 37, hole transfer layers 39 formed on the active layers 38 to facilitate delivery of the holes, and metal electrodes 40 formed on the hole transfer layers 39.

The transparent electrodes 32 may be formed from, for example, ITO, and the electron transfer layers 35 may be formed by coating a material such as, for example, thin lithium fluoride (Lif).

Further, the metal thin layers 36 formed on the electron transfer layers 35 may be coated with, for example, gold (Au) or nickel (Ni) as the catalyst for the synthesis of the carbon nano-tubes 37.

As will be explained below, the active layers 38 may be formed by synthesizing n-type doped carbon nano-tubes 37 with the metal particles contained in the metal thin layers 36 formed on the electron transfer layers 35 and depositing, by coating, blended polymer solution thereon.

To coat polymer solution on the doped carbon nano-tubes 37, for example, spin coating or air spraying may be used.

Furthermore, the hole transfer layers 39 formed on the active layers 38 may be formed by depositing a material such as PDOT:PSS (Poly(3,4-ethylenedioxythiophene) poly(styrenesulfonate)), and preferably use gold (Au) or a material with a larger work function.

The work function may preferably be 5.2 eV for metal electrodes 40, 5.00±1 eV for the hole transfer layers 39, 2.6 eV for the electron transfer layers 35, and 4.7 eV for the transparent electrodes 32.

As explained above, since the nano-wires 34 are grown on the transparent electrodes 32 and the active layers 38 are formed by synthesis with the carbon nano-tubes 37, electrons generated at the active layers 38 by the nano-wires 34 and the carbon nano-tubes 37 can be collected at the metal electrodes 40 more rapidly, while the loss of collected electrons is also controlled. As a result, increased efficiency is provided.

Further, as explained above, as the nano-wires 34 are grown on the transparent electrodes 32 and the active layers 38 are formed by synthesis with the carbon nano-tubes 37, surface area of the nano-wires 34 and the carbon nano-tubes 37 are maximized on both sides, and bonding interface also increases. As a result, increased efficiency is provided, compared to the conventional cases.

Further, by using nano-wires 34, light reflectivity decreases due to texturing effect, thus the efficiency increases. Since the nano-wires 34 are formed into conical configuration, organic matters are more easily adsorbed onto the nano-wires 34, which in turn brings in maximized surface area and facilitated electron transfer.

Further, as explained above, as the metal thin layers 36 are used as the catalyst so that the carbon nano-tubes 37 are directly grown on the nano-wires 34, captured electrons are attracted toward the metal electrodes 40 with speed and without loss of the captured electrons. Since the diameter of the carbon nano-tubes 37 is adjusted through the catalyst and thus band gap is adjusted, HOMO level and LUMO level are generated, which enable efficient electron transfer. As a result, increased efficiency is provided.

Further, due to strong UV blocking effect through the band gap adjustment of the nano-wires 34, photo-degradation of the organic matters is controlled and therefore, increased life-span is expected.

Additionally, through band gap adjustment, electron-hole pairs can also be generated within the carbon nano-tubes 37, and therefore, this further increases efficiency.

The characteristics mentioned above are possible, mainly because it is possible to adjust band gap of the solar cell during fabrication process, by adjusting the diameter of the carbon nano-tubes during fabrication of the carbon nano-tubes, using the inverse-proportional relationship between distance and band gap.

A manufacturing method of the nano-wire solar cells 21 will now be explained below.

First, referring to FIG. 3a, the transparent electrodes 32 are formed on the substrates 31, and then, referring to FIG. 3b, the seed layers 33 are formed on the transparent electrodes 32 to grown the nano-wires 34.

Next, referring to FIG. 3c, a plurality of nano-wires 34 are grown from the seed layers 33, and referring to FIG. 3d, the grown nano-wires 34 are dry- or wet-etched into the form of cone.

Referring to FIG. 3e, on the nano-wires 34 which are in conical configuration, the electron transfer layers 35 are formed. The electronc transfer layers 35 may be formed by coating a material such as thin lithium fluoride (Lif).

Next, referring to FIG. 3f, a material such as gold (Au) or nickel (Ni) is coated as a catalyst for the synthesis of the carbon nano-tubes 37, and the metal thin layers 36 are formed on the electron transfer layers 35.

Next, referring to FIG. 3g, the metal particles contained in the metal thin layers 36 are synthesized with the carbon nano-tubes 37 by the synthesis of the doped carbon nano-tubes 37.

The carbon nano-tubes 37 may be prepared separately and in advance, by growing separately from the process of growing the nano-wires 34 and doping the same.

Referring to FIG. 3h, blended polymer is coated on the carbon nano-tubes 37 which are bonded to the metal particles 36, so that the active layers 38, in which the carbon nano-tubes 37 and polymer are synthesized, are formed.

Referring to FIG. 3i, the hole transfer layers 39 are formed on the active layers 38 and then the metal electrodes 39 are formed. As a result, the nano-wire solar cells 21 using nano-wires are completely formed.

The hole transfer layers 39 may be formed by depositing a material such as PDOT:PSS as explained above, and the metal electrodes 40 may generally use gold (Au) or a material with larger work function.

The work function may preferably be 5.2 eV for metal electrodes 40, 5.00±1 eV for the hole transfer layers 39, 2.6 eV for the electron transfer layers 35, and 4.7 eV for the transparent electrodes 32.

Referring to the embodiments of the flag type hybrid solar cell combining a solar cell using nano-wire and a nano-generator using piezoelectric effect, and a manufacturing method thereof explained above, since the nano-wires 34 are grown on the transparent electrodes 32 and the active layers 38 are formed by synthesis with the carbon nano-tubes 37, electrons generated at the active layers 38 by the nano-wires 34 and the carbon nano-tubes 37 can be collected at the metal electrodes 40 more rapidly, while the loss of collected electrons is also controlled. As a result, increased efficiency is provided.

Further, by using nano-wires 34, light reflectivity decreases due to texturing effect, thus the efficiency increases. Since the nano-wires 34 are formed into conical configuration, organic matters are more easily adsorbed onto the nano-wires 34, which in turn brings in maximized surface area and facilitated electron transfer.

Further, as explained above, as the metal thin layers 36 are used as the catalyst so that the carbon nano-tubes 37 are directly grown on the nano-wires 34, captured electrons are attracted toward the metal electrodes 40 with speed and without loss of the captured electrons. Since the diameter of the carbon nano-tubes 37 is adjusted through the catalyst and thus band gap is adjusted, HOMO level and LUMO level are generated, which enable efficient electron transfer. As a result, increased efficiency is provided.

Further, due to strong UV blocking effect through the band gap adjustment of the nano-wires 34, photo-degradation of the organic matters is controlled and therefore, increased life-span is expected.

Further, as explained above, as the nano-wires 34 are grown on the transparent electrodes 32 and the active layers 38 are formed by synthesis with the carbon nano-tubes 37, surface area of the nano-wires 34 and the carbon nano-tubes 37 are maximized on both sides, and bonding interface also increases. As a result, increased efficiency is provided, compared to the conventional cases.

Additionally, through band gap adjustment, electron-hole pairs can also be generated within the carbon nano-tubes 37, and therefore, this further increases efficiency.

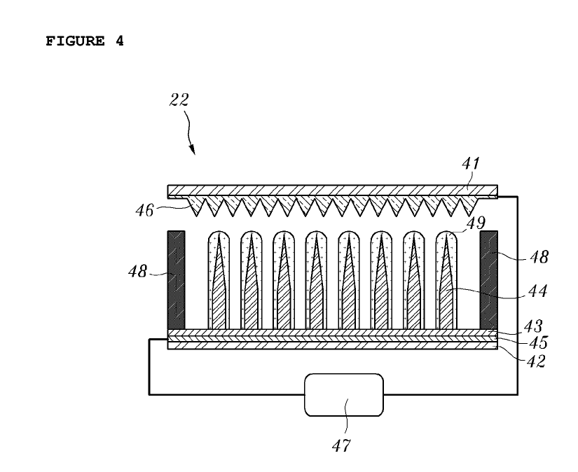

Referring now to FIG. 4, the detailed constitution of the nano-generators 22 using piezoelectric effect for use in the flag-type hybrid solar cell 10 of FIG. 1 will be explained in detail below.

FIG. 4 is a schematic view illustrating the constitution of the nano-generators 22 using piezoelectric effect for use in the flag-type hybrid solar cell 10 of FIG. 1.

Referring to FIG. 4, the nano-generators 22 using piezoelectric effect according to an embodiment of the present invention may include upper and lower substrates 41, 42 arranged on upper and lower surfaces, respectively, seed layers 43 formed on the lower substrates 42, a plurality of nano-wires 44 grown perpendicularly from the respective seed layers 43, lower electrodes 45 formed from conductive material in between the lower substrates 42 and the seed layers 43 to transfer electricity generated at the nano-wires 44 to outside, serrated upper electrodes 46 formed on the upper substrates 41, energy accumulating means 47 which accumulates electricity transferred from the respective electrodes 45, 46, supports 48 arranged on both left and right sides of the lower substrates 42 to prevent contact between the upper and lower substrates 41, 42, and coating layers 49 coated all around the nano-wires 44.

The respective substrates 41, 42 may be formed from flexible substrates for easy bending by the wind, and the energy accumulating means 47 may use an element such as a capacitor.

The coating layers 49 are formed as the polymer substance such as polyvinylidene fluoride (PVDF) on the respective nano-wires 44, to prevent breakage and also improve the characteristics of the nano-wires 44.

In the structure as explained above, when the nano-generators 40 are subject to force so that the upper and lower substrates 41, 42 are pressed toward each other or bent, electricity generated by the nano-wires 44 is collected at the energy accumulating means 47. Accordingly, power is generated, as the nano-wires 44 are repeatedly deformed.

When a material such as the PVDF with a high piezoelectric constant is coated on the nano-wires, more piezoelectricity is generated, compared to when simply the nano-wires are used.

To be specific, as the nano-wires are coated with a material such as PVDF with high piezoelectric constant, the surface area of the nano-wires is maximized, thus providing higher efficiency than when the nano-generators are constructed with the ZnO nano-wires only.

Further, the coating material is not limited to PVDF only. Accordingly, although an embodiment of coating nano-wires with PVDF is explained below, one will understand that any material with high piezoelectric constant is equally applicable.

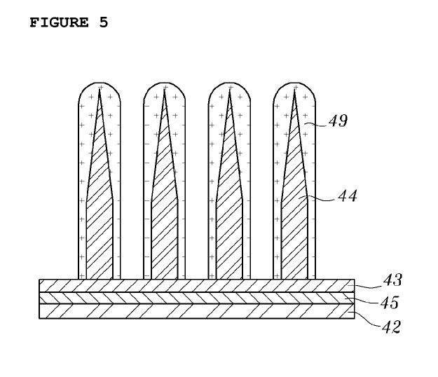

Referring to FIG. 5, the nano-generators 22 according to an embodiment includes pointed nano-wires 44.

FIG. 5 is an exploded view illustrating the constitution of the nano-wires 44 and the coating layers 49 of the nano-generators 22 of FIG. 4 in greater detail.

To be specific, conventionally, since the polymer material such as PVDF is coated on columnar nano-wires, the coating layers are formed only on the tips of the nano-wires and improperly formed on the sides thereof, which is disadvantageous. Referring to FIG. 5, the nano-generators 42 according to the present invention have the nano-wires 44 with pointed ends, thus allowing the coating material to reach the seed layers 43 of the lower substrates 42 so that the coating layers 49 are formed all around the nano-wires 44.

The manufacturing method of the nano-generators 22 using the piezoelectric effect will be explained below.

First, the upper and lower substrates 41, 42 are arranged on the upper and lower surfaces, respectively, and the serrated upper electrodes 45 are formed on the upper substrates 41, while the lower electrodes 46 formed from conductive material are formed on the lower substrates 42.

Next, the seed layers 43 to grow the nano-wires 44 are formed on the lower electrodes 46, and a plurality of nano-wires 44 are grown perpendicularly from the seed layers 43. The ends of the nano-wires 44 are formed to pointed pattern, so that the nano-wires 44 form overall conical configuration.

The supports 48 are then formed on both left and right ends of the lower substrates 42 to prevent contact between the upper and lower substrates 41, 42 and also to maintain a predetermined interval therebetween, and the energy accumulating means 47 are formed to accumulate the electricity as transmitted from the respective electrodes.

Next, polymer substance such as polyvinylidene fluoride (PVDF) is coated all around the nano-wires 44, so that the nano-generators 22 using piezoelectric effect are provided, which can improve characteristics of the nano-wires 44.

In an alternative embodiment, the nano-generators 22 using piezoelectric effect may be manufactured in the manner illustrated in FIG. 3 for the nano-wire solar cells 21 using nano-wires. Accordingly, the nano-generators 22 using piezoelectric effect may be manufactured by the manner of synthesizing carbon nano-tubes to nano-wires and then forming active layers by coating blended polymer.

Accordingly, with the flag type hybrid solar cell 10 according to the embodiments, the nano-wire solar cells 21 using nano-wires generate electromotive force during the days by absorbing solar beam, while the nano-generators 22 using piezoelectric effects generate electromotive force by micro-vibration of the nano-wires by the winds at nights.

Further, since the nano-generators 22 using piezoelectric effect can generate electricity days and nights as long as there are winds, the power generation during the days can be multiplied in addition to the power generation of the nano-wire solar cells 21.

That is, the present invention provides a flat type hybrid solar cell combining nano-wire solar cells 12 using nano-wires and nano-generators 22 using piezoelectric effect, so that it is usable anywhere as long as there are sunlight and winds. Further, due to the easy and simple fabrication, and easy installation which requires nothing but planting at an intended site, environmentally-friendly green energy can be obtained.

The foregoing exemplary embodiments and advantages are merely exemplary and are not to be construed as limiting the present invention. The present teaching can be readily coated to other types of apparatuses. Also, the description of the exemplary embodiments of the present inventive concept is intended to be illustrative, and not to limit the scope of the claims.

As explained above, according to various embodiments, the nano-wire solar cells using nano-wires absorb solar beam and thus generate electromotive force during the days, while the nano-generators using piezoelectric effect generate electromotive force with micro vibration of the nano-wires at nights.

Further, according to various embodiments, since the nano-generators using piezoelectric effect can generate electricity day and night and as long as there are winds, more power generation is possible in addition to the power generation by the nano-wire solar cells during the days.

According to various embodiments, a flag type hybrid solar cell is provided, which combines nano-wire solar cells and nano-generators using piezoelectric effect, which is easy to fabricate, usable anywhere as long as there are sun and the winds, and easy to install as it requires simple planting, and thus provides environmentally-friendly green energy.

What is claimed is:

1. A flag type hybrid solar cell capable of generating electricity irrespective of location of sun or presence or absence of sun beams, the flag type hybrid solar cell comprising:
a plurality of solar cells formed from a flexible substrate which is deformable by winds; and
a frame which fixes the solar cells, wherein
the solar cells comprise,
a plurality of nano-wire solar cells which generate electricity from solar beam using nano-wires; and
a plurality of nano-generators which generate electricity using piezoelectric effect, wherein
the nano-wire solar cells and the nano-generators using piezoelectric effect are connected to each other in a perpendicularly symmetrical relation to each other.

2. The flat type hybrid solar cell of claim 1, wherein the nano-wire solar cells comprise:
substrates;
transparent electrodes formed on the substrates;
seed layers formed no the transparent electrodes;
a plurality of nano-wires grown on the seed layers and formed into conical shape;
electron transfer layers which facilitate transfer of electrons collected at the nano-wires;
metal thin layers formed on the electron transfer layers;
a plurality of carbon nano-tubes which are synthesized with metal particles contained in the metal thin layers;
active layers formed as a result of the synthesis of the carbon nano-tubes and coating of blended polymer;
hole transfer layers formed on the active layers to facilitate the transfer of the holes; and
metal electrodes formed on the hole transfer layers.

3. The flag type hybrid solar cell of claim 2, wherein the transparent electrodes are formed from ITO.

4. The flag type hybrid solar cell of claim 2, wherein the nano-wires are formed into the conical shape by dry or wet etching.

5. The flag type hybrid solar cell of claim 2, wherein the electron transfer layers are formed by coating thin lithium fluoride (Lif).

6. The flag type hybrid solar cell of claim 2, wherein the metal thin layers are formed by coating gold (Au) or nickel (Ni) as a catalyst for the synthesis of the carbon nano-tubes.

7. The flag type hybrid solar cell of claim 2, wherein the active layers are formed as a result of synthesizing the carbon nano-tubes, doped in n-type, to the metal particles contained in the metal thin layers, and coating blended polymer solution.

8. The flag type hybrid solar cell of claim 7, wherein the polymer solution is coated using spin coating or air spraying.

9. The flag type hybrid solar cell of claim 2, wherein the electron transfer layers are formed by depositing poly(3,4-ethylenedioxythiophene) poly(styrenesulfonate) (PDOT:PSS).

10. The flag type hybrid solar cell of claim 2, wherein the metal electrodes are formed by using gold (Au) or a material having 5.2 eV of work function.

11. The flag type hybrid solar cell of claim 1, wherein the nano-generators using piezoelectric effect comprise:
upper and lower substrates arranged on upper and lower surfaces, respectively;
seed layers arranged on the lower substrates;
a plurality of nano-wires grown on the seed layers in perpendicular direction, respectively;
lower electrodes arranged between the lower substrates and the seed layers to transmit electricity generated at the nano-wires to outside, and formed from conductive material, and upper electrodes in serrated form formed on the upper substrates;
energy accumulating means for accumulating the electricity transmitted from the respective electrodes;
supports arranged on both left and right ends of the lower substrates to prevent contact between the upper substrates with the lower substrates and to maintain a predetermined interval therebetween; and
coating layers coated all around the nano-wires, respectively

12. The flag type hybrid solar cell of claim 11, wherein the nano-wires are formed into conical shape.

13. The flag type hybrid solar cell of claim 11, wherein the coating layers are formed from polymer material comprising polyvinylidene fluoride.

14. A method for manufacturing a flag type hybrid solar cell capable of generating electricity irrespective of location of sun or presence or absence of sun beams, the method comprising:
fabricating a plurality of solar cells deformable by winds, using a flexible substrate; and
fabricating a frame to fix the solar cells, wherein
the fabricating the plurality of solar cells comprises,
fabricating a plurality of nano-wire solar cells which generate electricity from solar beam using nano-wires,
fabricating a plurality of nano-generators which generate electricity using piezoelectric effect, and
connecting the nano-wire solar cells and the nano-generators using piezoelectric effect to each other in a perpendicularly symmetrical relation to each other.

15. The method of claim 14, wherein the fabricating the nano-wire solar cells comprises:
forming transparent electrodes on substrates;
forming seed layers to grow nano-wires on the transparent electrodes;
growing a plurality of nano-wires on the seed layers;
shaping the grown nano-wires into conical configuration;
forming electron transfer layers on the respectively-shaped nano-wires;
forming metal thin layers on the electronic transfer layers for synthesis of the nano-wires with carbon nano-tubes;
synthesizing metal particles contained in the metal thin layers with the carbon nano-tubes by coating the carbon nano-tubes on the metal thin layers;
forming active layers on the synthesized carbon nano-tubes;
forming hole transfer layers on the active layers; and
forming metal electrodes on the hole transfer layers.

16. The method of claim 15, wherein the forming the transparent electrodes uses ITO.

17. The method of claim 15, wherein the shaping comprises shaping the nano-wires into the conical configuration by dry or wet etching.

18. The method of claim 15, wherein the forming the electron transfer layers comprises coating Lif.

19. The method of claim 15, wherein the forming the metal thin layers comprises coating gold (Au) or nickel (Ni).

20. The method of claim 15, wherein the forming the active layers comprises synthesizing the metal particles contained in the metal thin layers with the carbon nano-tubes which are n-type doped, and coating blended polymer solution.

21. The method of claim 20, wherein the forming the active layers comprise coating the polymer solution using spin coating or air spraying.

22. The method of claim 15, wherein the forming the hole transfer layers comprises depositing PDOT:PSS.

23. The method of claim 15, wherein the forming the metal electrodes comprises using gold (Au) or a material corresponding to 5.2 eV of work function.

24. The method of claim 14, wherein the fabricating the nano-generators using piezoelectric effect comprises:
forming upper and lower substrates arranged on upper and lower surfaces, respectively;
forming lower electrodes formed from conductive material on the lower substrates;
forming seed layers on the lower substrates to grow nano-wires;
forming serrated upper electrodes on the upper substrates;
installing energy accumulating means to accumulate electricity transmitted from the respective electrodes;
installing supports on both left and right ends of the lower substrate to prevent contact between the upper substrates and the lower substrates and to maintain a predetermined interval therebetween;
growing a plurality of nano-wires on the seed layers to a perpendicular direction; and
coating layers all around the respective nano-wires.

25. The method of claim 24, wherein the growing the nano-wires comprises forming ends of the nano-wires to a conical shape.

26. The method of claim 24, wherein the coating comprises coating a polymer material comprising polyvinylidene fluoride (PVDF) all around the nano-wires.
